(19) United States
(12) Patent Application Publication
(10) Pub. No.: US 2025/0284176 A1
(43) Pub. Date: Sep. 11, 2025

(54) Nonlinear Bound States in the Continuum for Intensity Squeezing and Generation of Large Photonic Fock States

(71) Applicant: Massachusetts Institute of Technology, Cambridge, MA (US)

(72) Inventors: Nicholas H. Rivera, Somverville, MA (US); Jamison Michael Sloan, Somerville, MA (US); Yannick Salamin, Arlington, MA (US); Marin Soljacic, Belmont, MA (US)

(21) Appl. No.: 18/231,529

(22) Filed: Aug. 8, 2023

Related U.S. Application Data
(60) Provisional application No. 63/416,818, filed on Oct. 17, 2022.

(51) Int. Cl. G02F 1/35; G02F 1/355; H10N 60/12

(52) U.S. Cl. CPC G02F 1/3511; G02F 1/3523; G02F 1/3553; G02F 1/3556; H10N 60/12

(57) ABSTRACT

A fundamental new effect in nonlinear photonic systems is disclosed herein, called n-photon bound states in the continuum, which can be applied to deterministically create large Fock states, as well as very highly intensity-squeezed states of light. The effect is one in which destructive interference gives a certain quantum state of light an infinite lifetime, despite coexisting in frequency with a radiative continuum. For Kerr nonlinear systems, that state is an n-photon (Fock) state of a particular and tunable n. Experimentally-realizable examples are shown which are capable of producing n-photon Fock states, and states with very large intensity squeezing, such as greater than 10 dB. The effect requires only Kerr nonlinearity and linear frequency-dependent (non-Markovian) dissipation, and is, in principle, applicable at any frequency. The theory and concepts are also immediately applicable to nonlinear bosons besides photons, and thus may be implemented in many other disciplines.

This application claims priority of U.S. Provisional Application Ser. No. 63/416, 818, filed Oct. 17, 2022, the disclosure of which is incorporated herein by reference in its entirety.

This invention was made with government support under FA9550-20-1-0115 awarded by the Air Force Office of Scientific Research, and W911NF-18-2-0048 awarded by the U.S. Army Research Office. The government has certain rights in the invention.

### BACKGROUND

Much of the current focus in quantum optics is directed to the generation and application of quantum states of light, such as single-photons, entangled photon pairs, cluster states, and quadrature-squeezed light. Such states enable the extension of important applications, such as information processing, simulation, precision measurement, and communication, beyond the limits imposed by classical physics. While these states are already useful, a transformation of the quantum landscape is expected if macroscopically non-classical (e.g., non-Gaussian) states of light, which offer a unique degree of quantum advantage, can be deterministically realized and manipulated.

As a concrete example, consider the case of large optical Fock states |n [symbol] which are eigenstates of the quantized radiation field with a perfectly defined number of photons. These states are, especially in optics, currently very difficult to realize, and despite this, have long been identified by the quantum community as an important state to access. For example, such states have long been considered for quantum metrology because they have a perfectly defined intensity that would enable measurements without shot noise. One of the earliest proposed applications along these lines was to use an n-photon state in a cavity as an extremely sensitive sensor of small vibrations. These states are also considered valuable in simulation and information processing tasks. For example, in the microwave domain, Fock states of LC resonators have already been used for quantum chemistry tasks, such as simulating vibronic spectra of molecules. In particular, high-order Fock states of the resonator can be mapped to highly electronically and vibrationally excited states of a molecule, enabling simulation f excited-state spectra, which is traditionally challenging. Another high-profile application of large Fock states for simulation is in the implementation of quantum algorithms such as boson sampling (or gaussian boson sampling): a “modest” (multimode) Fock state of even 100 photons enables computations of matrix permanents at least fifteen orders of magnitude larger than could be handled by even the largest supercomputers today. Fock states are also important “resource states”, providing a vehicle to generate other desirable quantum states. For example, small Fock states can be used to generate (squeezed) Schrodinger cat states, and could further be used to generate states such as displaced Fock states, GKP states, etc. Beyond all of these “applications”-oriented arguments, there is also a clear case for the interest in these states on purely fundamental grounds.

For the reasons above and many more, the problem of generating Fock states has generated much attention at both microwave and optical frequencies. At microwave frequencies, it is currently possible to deterministically, and with high fidelities (>90%), produce Fock states of up to 15 photons. These Fock states are generated in microwave resonators via quantum optimal control algorithms that simultaneously employ external driving of the cavity by microwave pulses and superconducting transmon qubits. Fock states have also been generated in microwave cavities by strongly coupling them to transmon qubits that are repeatedly pumped to inject photons into the cavity at deterministic times. Even older work made use of Rydberg atoms strongly coupled to microwave cavities in order to generate low-order Fock states using principles such as the one above, as well as quantum feedback protocols. Such Rydberg atom-cavity interactions form the basis for new theoretical proposals to extend microwave Fock states to higher photon numbers.

In optics, the situation is markedly different. As there is no real analogue of superconducting qubits for optics, the techniques above cannot be applied to generate photonic Fock states. In fact, it is currently a significant challenge to deterministically produce Fock states in optics even with order larger than n=2. This lies in stark contrast to single photon Fock states, where the capabilities are much more mature. In general, proposals for generating Fock states with n≥2 are either non-deterministic (meaning the state is generated with random order, or at random times), or require intermediate creation of hard-to-generate states (such as atomic Dicke states).

Therefore, a system and method to generate these large optical Fock states would be advantageous.

### SUMMARY

Large non-Gaussian states of light are a highly coveted resource in quantum science and technology. An important example of such states are n-photon states of light (Fock states), which, besides being the most fundamental states of the quantized radiation field, are theoretically believed to be valuable for many tasks including metrology, communication, simulation, quantum state generation, and information processing. However, the deterministic creation and stabilization of even approximate large-number (n≥2) Fock states at optical frequencies is a long-standing open problem. A fundamental new effect in nonlinear photonic systems is disclosed herein, called n-photon bound states in the continuum, which can be applied to deterministically create large Fock states, as well as very highly intensity-squeezed states of light. The effect is one in which destructive interference gives a certain quantum state of light an infinite lifetime, despite coexisting in frequency with a radiative continuum. For Kerr nonlinear systems, that state is an n-photon (Fock) state of a particular and tunable n. Experimentally-realizable examples are shown which are capable of producing 30-photon Fock states, and states with very large intensity squeezing, such as greater than 10 dB. The effect requires only Kerr nonlinearity and linear frequency-dependent (non-Markovian) dissipation, and is, in principle, applicable at any frequency. The theory and concepts are also immediately applicable to nonlinear bosons besides photons, and thus may be implemented in many other disciplines, such as superconducting circuits, magnonics, and phononics. Further, engineered nonlinear photonic structures with highly tailorable radiation loss may be utilized as a basis to create many of the other quantum photonic states that have traditionally been challenging to generate.

In one embodiment, an apparatus for storing electromagnetic energy is disclosed. The apparatus comprises an electromagnetic resonator, and a nonlinear medium; wherein the electromagnetic resonator contains a resonance whose lifetime τ depends on resonance frequency (τ=τ(ω)) and/or wherein the electromagnetic resonator contains a resonance whose lifetime τ depends on a spatial distribution of its index of refraction, n(r), wherein r denotes a spatial position of constituent components of the electromagnetic resonator, that such τ=τ(n(r)). In some embodiments, the dependence of the resonance lifetime on frequency has a maximum as a function of frequency and/or wherein the dependence of the resonance lifetime on index of refraction has a maximum as a function of the index of refraction distribution, or the index of refraction of any one constituent component of the electromagnetic resonator.

In some embodiments, the nonlinear medium is a second-order nonlinear medium, and is one of KDP, KTP, BBO, LN, and PPLN.

In some embodiments, the nonlinear medium is a third-order nonlinear medium (a Kerr nonlinear medium). In certain embodiments, the nonlinear medium is GaAs, Ge, ZnTe (and general semiconductors), Si, Si₃N₄, GaP, silica, As₂S₃, As₂Se₃, other chalcogenide glasses, CS₂ or other nonlinear gases.

In some embodiments, the nonlinear medium is realized by a semiconductor quantum well (sustaining excitons) in close proximity to the electromagnetic resonator. In certain embodiments, the semiconductor quantum well is comprised of GaAs, WS₂, wSe₂, MoS₂, MoSe₂ or other transition metal dichalcogenides.

In some embodiments, the electromagnetic resonator is built from two ring resonators coupled evanescently to a waveguide; wherein either one or both resonators contain the nonlinear medium. In some embodiments, the apparatus includes at least one additional waveguide, wherein the at least one additional waveguide is coupled to either one or both resonators.

In some embodiments, the electromagnetic resonator is built from two photonic crystal defect cavities, coupled to a single photonic crystal waveguide, wherein either one or both resonators contain the nonlinear medium. In certain embodiments, the apparatus includes at least one additional waveguide, wherein the at least one additional waveguide is coupled to either one or both resonators.

In some embodiments, the electromagnetic resonator is realized by a photonic crystal slab with a resonance at some wavevector, whose lifetime achieves a sharp maximum as a function of wavevector, or index of refraction. In some embodiments, the photonic crystal slab material is also a nonlinear medium, or the photonic crystal slab is in proximity to a nonlinear medium. In some embodiments, the electromagnetic resonator is realized by a photonic crystal slab terminated laterally by a photonic crystal heterostructure.

In some embodiments, the electromagnetic resonator is a single ring resonator, coupled to one or more optical waveguides; with one of the optical waveguides being terminated on one end by a broadband reflector.

In some embodiments, the electromagnetic resonator is a photonic crystal defect cavity, coupled to one or more photonic crystal defect waveguides, with one of the photonic crystal waveguides being terminated by a backreflector, which is realized through a photonic bandgap.

In some embodiments, the electromagnetic resonator and nonlinearity are realized by coupling one weakly anharmonic Josephson junction, realizing Kerr nonlinearity, and a LC resonator, to a common transmission line. In some embodiments, the electromagnetic resonator and nonlinearity are realized by coupling one weakly anharmonic Josephson junction, realizing Kerr nonlinearity, to a transmission line which is terminated on one end by a microwave reflector.

In another embodiment, an apparatus for preparing quantum mechanical states of radiation, including sub-Poissonian states and Fock states, in a single resonant optical cavity, is disclosed. The apparatus comprises the apparatus described above and a pulsed laser, to inject initial photons into the resonant optical cavity. In certain embodiments, the pulsed laser is between 1 fs and 1 ps in duration

In another embodiment, an apparatus for preparing quantum mechanical states of radiation, including sub-Poissonian states and Fock states, in a single resonant optical cavity, is disclosed. The apparatus comprises the apparatus described above and a continuous wave laser, to pump photons into the resonant optical cavity.

In another embodiment, an apparatus for storing electromagnetic energy at any frequency is disclosed. The apparatus comprises a cavity containing: an electromagnetic resonator, and a nonlinear medium; wherein the electromagnetic resonator contains a resonance whose lifetime τ depends on a number of photons in the cavity, or equivalently, an intensity in the cavity.

In another embodiment, an apparatus for preparing quantum mechanical states of radiation, including sub-Poissonian states and Fock states, which is freely propagated in free space, is disclosed. The apparatus comprises a nonlinear system which imparts a transformation to an optical spectrum of an incident light pulse; and a spectral filter to induce nonlinear loss for light emitted from the nonlinear system. In some embodiments, the nonlinear system is an optical fiber with dispersion and the spectral filter is a Bragg filter, a filter with a Fano lineshape, or a Fabry-Perot filter. In some embodiments, the apparatus comprises a chain having a plurality of elements, wherein each element of the chain comprises the optical fiber and the spectral filter, to realize successive optimal filtering of the incident light.

### BRIEF DESCRIPTION OF THE DRAWINGS

For a better understanding of the present disclosure, reference is made to the accompanying drawings, in which like elements are referenced with like numerals, and in which:

FIGS. 1A-1C show photonic systems to realize a resonance with a photon-number-dependent loss rate according to various embodiments;

FIG. 1D shows nonlinear loss for a resonance coupled to a waveguide terminated by a backreflector;

FIG. 1E shows the loss and frequency associated with a BIC;

FIG. 1F shows graphs of photon number vs. nonlinear loss;

FIGS. 2A-2E show the dynamics of quantum statistics of a cavity undergoing nonlinear radiation loss;

FIG. 3A shows a system to realize BICs and sizeable Kerr nonlinearity simultaneously;

FIG. 3B shows the pump-and-ringdown protocol for deterministic creation of Fock states;

FIG. 3C shows evolution of the photon probabilities in time for the same initial state with different resonator frequencies;

FIG. 3D shows time-dependent photon-number squeezing for different levels of external linear loss; and

FIGS. 4A-4E show resonator geometries for realizing a frequency-dependent lifetime within optical and microwave systems.

### DETAILED DESCRIPTION

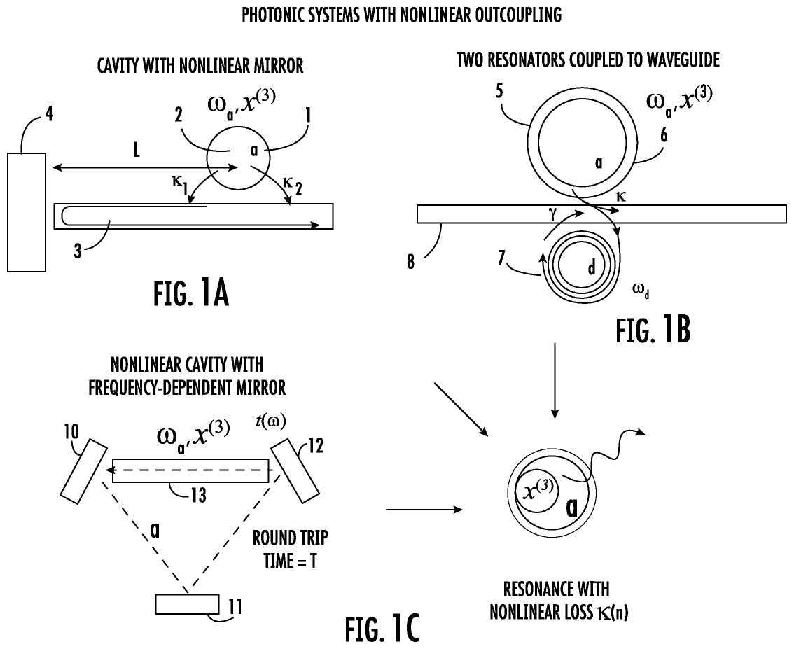

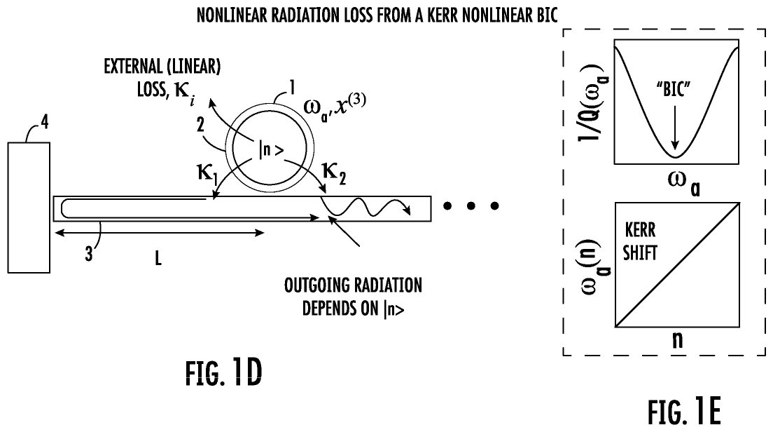

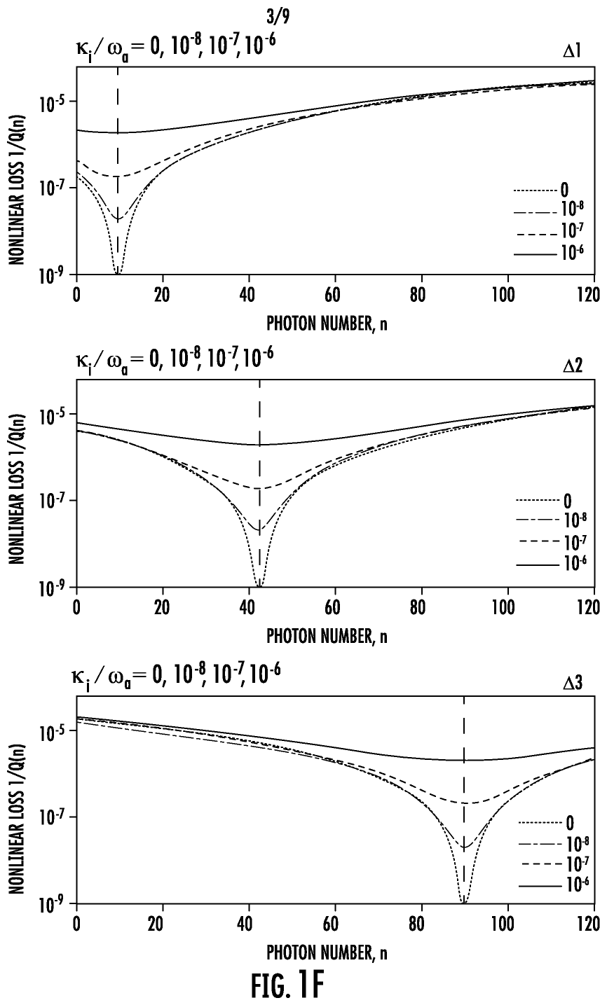

A new dissipative effect for photons, and a set of devices that can be used to deterministically generate Fock states of arbitrary order is disclosed. This set of devices may be applied at optical frequencies. Specifically, a general quantum theory of nonlinear leaky resonators with frequency-dependent outcoupling is presented, describing the dynamics of dissipation in photonic structures such as those shown in FIGS. 1A-1C. Additionally, a new effect that arises from this theory is disclosed, and is referred to as n-photon bound states in the continuum (BICs). In this effect, a photonic resonance may have infinite lifetime, conditioned on the resonance being in the state |n [symbol] . This leads to a situation where a Fock state is stable and dissipationless, even in the absence of pumping. Further, it is shown how these n-photon BICs enable deterministic generation of optical Fock states and highly intensity-squeezed states of light. Nonlinear photonic architectures to realize these n-photon BICs are shown, and a protocol is developed to deterministically create Fock states using them. This protocol includes injecting a short pulse from a laser into the nonlinear cavity, and letting the light decay freely from that cavity, such that Fock and highly squeezed states become naturally produced.

First, a description of the new effects and the intuition behind them is presented. The physics of interest is that of radiation loss in photonic resonators with Kerr nonlinearity. A special type of photonic resonator, of which FIGS. 1A-1C show three embodiments, is considered. All three structures have a common characteristic in that they can have very high Q-resonances due to destructive interference between two or more “paths” for light in the resonator (labeled a) to escape to the continuum.

Optical resonators without nonlinearity, where high-Q arises from destructive interference between radiation loss pathways, have been the subject of many recent works in the photonics community, under names like bound states in the continuum (BICs), quasi-bound states in the continuum (quasi-BICs), and Fano resonances. Characteristic to these high-Q resonances is that their Q-factor sensitively depends on geometrical and material parameters (e. g., feature size, index of refraction, photon wavevector), achieving a large maximum for some value of the parameters. This maximum occurs for the geometrical parameters which lead to opposite phases for the two leakage paths. When this occurs, the Q is limited only by what is referred to as “external” losses, such as absorption and scattering. Throughout this disclosure, the term BIC is used to refer to “cancellation-induced” high-Q resonances, consistent with previous usage of the phrase. Note that, despite many of these structures being theoretically unable to achieve literally infinite quality factor, due to their finite extent, they still, to good approximation, realize all the effects arising from the ideal case.

Now, consider the quantum optics of dissipation due to light leakage in structures with BICs. At first glance, it seems that the quantum optics of radiation loss of these nonlinear high-Q resonances would simply be governed by the textbook theory of dissipation in nonlinear high-Q resonators. The conventional theory has been applied extensively for over forty years, predicting a variety of effects which have been observed, such as optical bistability (in the classical domain), dissipative phase transitions, and modest amplitude squeezing (antibunching of light) in the cavity mode. This assumption, that it is only the value of Q that matters, is surprisingly not correct.

FIGS. 1A-1C show systems with quantum nonlinear dissipation based on leaky modes with frequency-dependent outcoupling, and n-photon BICs. FIG. 1A shows a resonator 1, having a frequency ωa. The resonator 1 may be a ring resonator or a defect resonator. The resonator 1 contains a medium 2 with a nonlinear loss. This nonlinear loss may be third order. The resonator 1 is evanescently coupled to a cavity 3, which may be a waveguide. One end of the cavity 3 is terminated with a broadband reflector, such as a highly reflective mirror 4. The coupling of the resonator 1 to the cavity 3 creates two paths for radiation, a first path (κ1) moving toward the mirror 4 and a second path (κ2) moving away from the mirror 4. By proper selection of lengths and other parameters, it is possible to create destructive interference, allowing the coupling of the resonator 1 to the cavity 3 to vanish for a certain resonator frequency.

FIG. 1B shows another system where two resonators 5, 7 are coupled to a cavity 8, which may be a waveguide. These resonators may be ring resonators or defect resonators. The first resonator 5 has a frequency of ωa and may contain a nonlinear medium 6. The second resonator 7 has a frequency of ωd. In some embodiments, the second resonator 7 may also contain a nonlinear medium. In other embodiments, the second resonator 7 does not include a nonlinear medium. The radiation paths κ and γ are coupled to the cavity 8. This configuration can also be realized in the case where the two resonators are defect resonators of a photonic crystal, and the waveguide is a defect waveguide of the photonic waveguide.

FIG. 1C shows a ring cavity formed by three mirrors 10, 11 and 12. Two of these mirrors 10, 11 are highly reflective. The third mirror 12 has a frequency dependent transmission coefficient. The path between two of these mirrors contains a nonlinear medium 13.

Each of these configurations has a resonator that has a nonlinearity and an outcoupling, through leaky mirrors, waveguides or external resonators. This outcoupling is dependent on the resonance frequency of the resonator.

In summary, the essential requirements for configurations to realize low noise optical states, such as Fock and sub-Poissonian states, follow. All of the configurations in FIGS. 1A-1C share the following characteristics.

First, they each feature an electromagnetic resonator in which the lifetime (or equivalently quality factor) of the resonance is dependent on the spatial distribution of the refractive index of the structure n(r). In FIGS. 1A and 1B, the precise position of the defect cavity (A) or ring resonators (B) affects the lifetime or quality factor of the resonance. In FIG. 1C, the value of the index of refraction of the included nonlinear medium 13 also affects the lifetime. The precise placement of the resonators with respect to the reflector, as well as the values of the indices of refraction of all of the components within the resonator dictates the spatial dependence of the refractive index distribution. An electromagnetic resonator is defined as any structure with a long-lived electromagnetic mode (for which optical frequency modes are a special case). Further note that this definition of optical resonator includes a wide variety of examples, including defect cavities in photonic crystals, ring cavities, Fabry-Perot resonances in open mirror cavities, and so on. The only requirement is having a resonance, corresponding to a localized distribution of electromagnetic energy.

The second key component of the configurations is nonlinearity: nonlinearity leads to a refractive index (and therefore, a refractive index distribution) which depends on the intensity of light inside the resonance.

The effect of these two components together is to have a system where the lifetime or quality factor of the resonance is dependent on the intensity of light (proportional to the number of photons) inside the resonance. Especially interesting are cases (see FIG. 1D) where the loss has a minimum as a function of intensity (equivalently, the quality factor and the lifetime have a maximum as a function of light intensity).

Also note that there is explicitly a special case of a resonance whose lifetime depends on the spatial distribution of the refractive index: a resonance whose lifetime depends on the resonance frequency ω. The resonance frequency is a function of the refractive index distribution, and therefore the lifetime is as well.

Consider what happens when Kerr nonlinearity is added to the resonance a (for example, when the resonator in FIG. 1A has third-order optical nonlinearity). In that case, the refractive index depends on intensity, or equivalently, the number of photons, n, in the cavity. Then, as the intracavity photon number changes, so does the resonance frequency ω_{α}, and also the relative phases of leakage paths in FIG. 1A. In such a case, the Q-factor depends on the number of photons in the cavity: Q=Q(n)=Q(ω_{α}(n)): it is the composition of the dependence of Q=Q(ω_{α}) on the resonator frequency (amplitude-phase coupling) and the dependence of the resonator frequency ω_{α}=ω_{α}(n) on the photon number (because of the Kerr nonlinearity). This system therefore has nonlinear loss: a decay rate κ(n) that depends on the number of photons in the non-linear electromagnetic resonator.

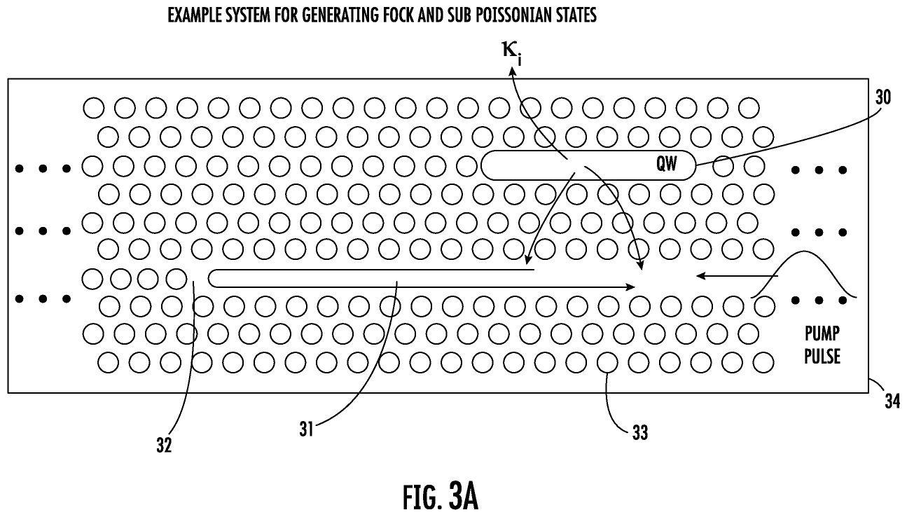

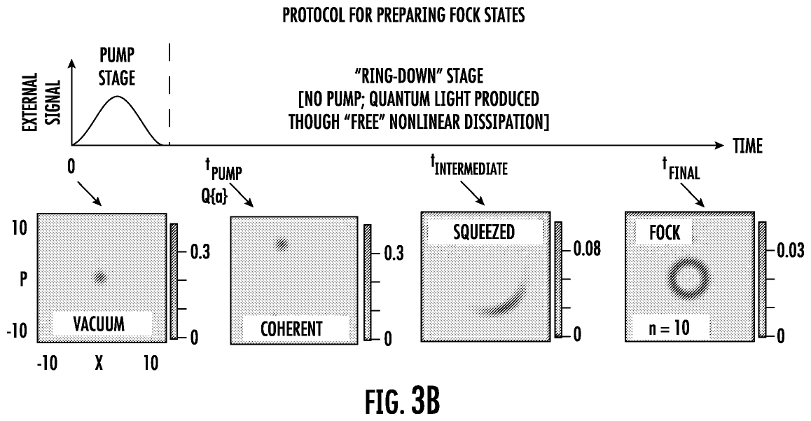

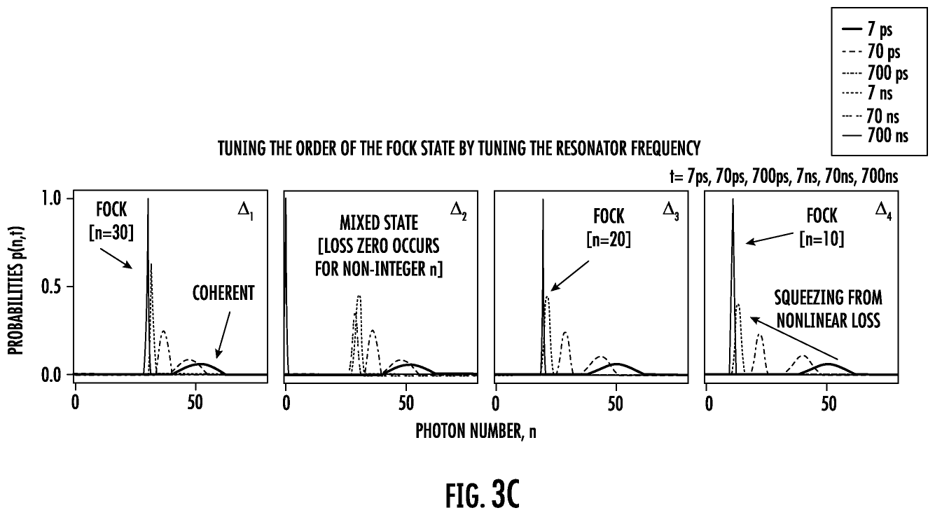

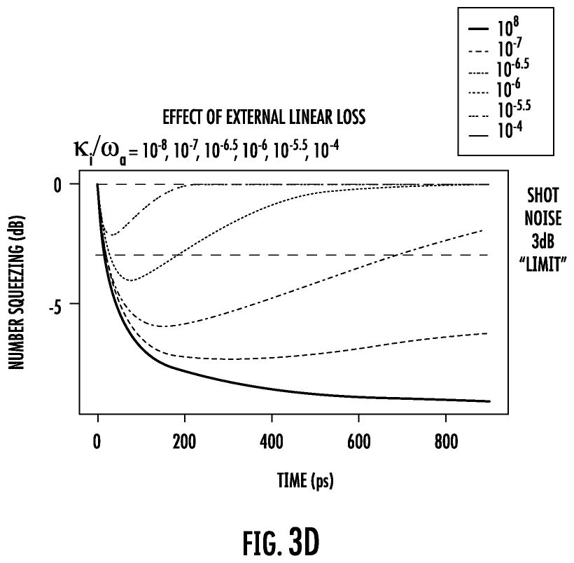

Another class of embodiments which satisfies these conditions are the set of resonators which may be created by means of photonic crystals. Photonic crystals are optical systems in which the refractive index is periodic in one or more spatial dimensions. Resonators can be created by introducing defects into photonic crystals. For example, as shown in FIG. 3A, a photonic crystal slab 34 (such as a thin film) has a two-dimensionally periodic array of holes 33 etched into the slab. By filling a single hole (or simply not etching the region where a hole was supposed to be), electromagnetic energy can be localized to the vicinity of this filled or missing hole. This may be referred to as a defect resonator or defect cavity. Note that cavity is often used interchangeably with resonator, even if the cavity does not have an excavated region of free space. Additionally, by filling a line of holes, light can be localized to the region defined by the filled holes: in other words, the line-defect acts as a waveguide 31 (called a defect waveguide). Photonic crystal versions of FIGS. 1A and 1B can readily be considered. The photonic crystal version of FIG. 1A has a defect resonator and a defect waveguide. The photonic crystal version of FIG. 1B has two photonic crystal defect resonators on opposite sides of a defect waveguide. A waveguide which is terminated (representing for example a region where holes are not filled) acts as a reflector for light propagating in the defect waveguide, also providing the necessary reflector in FIG. 1A. The reflector may also be created by means of a photonic crystal heterostructure, which is an abrupt interface between photonic crystals of two different periodicities.

Another unique type of photonic crystal resonator may be constructed. In photonic crystal slabs, it is possible to localize light to the slab without explicit mirrors: such perfect confinement (with infinite quality factor) occurs at a given in-plane wavevector of light. The exact wavevector depends on the periodicity of the holes and the index of refraction of the slab. Additionally, if there is such a resonance (called a bound state in the continuum) at this wavevector, varying the index of refraction will sweep through a region of large quality factor. In this case, if the index of refraction were to be varied, the quality factor would pass through a sharp maximum, as is needed for the disclosed configurations.

In any of these photonic crystal resonators, the nonlinearity may be in the material slab itself, or it may be in a material which is deposited on top of the resonator, within a few wavelength distance from the resonator, so that the nonlinear medium is in contact with the evanescent field of the resonator.

Kerr nonlinear BICs realize a very unique form of nonlinear loss for photons compared to well-known forms of nonlinear loss, like saturable or multiphoton absorption. This is illustrated in FIGS. 1D-1E, where the nonlinear loss rate as a function of photon number is plotted. FIG. 1D illustrates the nonlinear loss for a resonance 1 coupled to a waveguide 3 terminated by a backreflector 4, such as that shown in FIG. 1A. As noted above, there are two radiation paths, κ1 and κ2. Additionally, there is external loss, κi, which may be linear. FIG. 1E shows the loss and the frequency of the resonator. As noted above, there may be a resonator frequency results in a minimum loss. Due to the Kerr nonlinearity, the resonator frequency is a linear function of the intracavity photon number (n).

FIG. 1F shows a photon-number dependent loss for the cavity. In the case of a true BIC, where the lifetime of the resonance becomes infinite, the loss becomes zero for some photon number n₀−a structure having an n₀-photon BIC. For a quasi-BIC, the loss reaches a minimum, rather than a zero, for that same photon number. Changing the detuning of the resonator from the BIC frequency changes the zero-loss-photon-number. The top graph shows the nonlinear loss compared to photon number when the resonator is tuned to a first value of roughly 10 photons. The middle graph shows this relationship when the resonator is tuned to a second value of roughly 42 photons. The bottom graph shows this relationship when the resonator is tuned to a third value of roughly 90 photons. Note that in each scenario, as the ratio of κi to ωa increases, the nonlinear loss also increases. The parameters used in this figure are: ω_{α}=1.47 eV, Δω=10⁻²ω_{α, T}⁻¹=10⁻³ω_{α}, β5×10⁻⁶ω_{α}.

As anticipated from the disclosure above, there is a maximum in Q (minimum in κ) as a function of photon number. For the case of an ideal BIC (infinite lifetime), there is a special photon number n₀ for which the loss is exactly zero κ(n₀)=0. This structure is said to have an n₀-photon BIC, since when it has n₀ photons, the resonance lifetime is infinite.

It is clear that such a system might facilitate creation of n₀-photon Fock states. Suppose the system is populated with an average number of photons n̅ greater than n₀ (for example, a coherent state with a mean and variance of n̅ photons. Then the system will decay until it has n₀ photons exactly (with zero variance). The system will stay stuck in the state |n₀ [symbol] because the loss rate is zero in that state, and the photons have nowhere to go at that point. Thus, the variance (fluctuations) have disappeared entirely. By continuity, even when the BIC is imperfect due to some finite external loss κᵢ (see FIG. 1D), one expects the variance in photon number to rapidly drop (well below the mean), leading to intensity-squeezed (nonclassical) light. That said, if the background loss is too high, these quantum optical effects will be mitigated, as the nonlinear loss looks basically linear (intensity-independent, see curves associated with high κi/ωa ratios in FIG. 1F), converging to textbook dissipation theory.

For a resonance a with frequency-dependent coupling to a set of radiation channels (indexed by i), the quantum mechanical equation of motion of that resonance is:

$$\dot{a} = i {ω}_{a} a - 2 i {βω}_{a} {a}^{†} {a}^{2} - \int {dt}^{′} {K}_{l} ( t - {t}^{′} ) a ( {t}^{′} ) + i {\sum }_{i} \int {dt}^{′} {K}_{c , i} ( t - {t}^{′} ) a ( {t}^{′} ) ,$$

where K_{c,i}(ω) (the Fourier transform of the time-domain version above) represents the frequency-dependent coupling of light, incident from input channel i, at frequency ω, into the resonator. The function Kₗ(ω) is related to the incoupling function via

$${K}_{l} ( ω ) {\sum }_{l} {K}_{l , i} ( ω ) , with {K}_{l , i} ( ω ) ≡ i \int \frac{d {ω}^{′}}{2 π} {K}_{c , i} ( ω ) / [ ω - {ω}^{′} + i η ]$$

and the frequency-dependent lifetime of the resonance is defined as τ(ω)=(2Re Kₗ(ω))⁻¹. The resulting equation of motion for the density matrix of the resonance is given by:

$$\dot{ρ} = - i [ {H}_{K} + {H}_{d} , ρ ] + D [ ρ ] , \qquad ( 1 )$$

$$where$$

$${H}_{K} + {H}_{d} = {ω}_{a} {a}^{†} a + {βω}_{a} {a}^{†2} {a}^{2} + α ( t ) a + {α}^{*} ( t ) {a}^{†} \qquad ( 2 )$$

is responsible for the conservative parts of the evolution of the resonance, and the dissipator D[τ] is defined through its matrix elements as (m, n denote Fock states):

$$〈 m \vert D [ ρ ] \vert n 〉 = - ( {mK}_{l} ( {ω}_{m , m - 1} ) + {nK}_{l}^{*} ( {ω}_{n , n - 1} ) ) {ρ}_{mn} + \sqrt{( m + 1 ) ( n + 1 )} ( {K}_{l} ( {ω}_{m + 1 , m} ) + {K}_{l}^{*} ( {ω}_{n + 1 , n} ) ) {ρ}_{m + 1 , n + 1} \qquad ( 3 )$$

where ω_{m,m-1}=ω_{α}(1+2βm), with β the single-photon nonlinear coefficient of the medium.

When the frequency-dependent loss has a zero or a minimum and is combined with Kerr nonlinearity, then sub-Poissonian and Fock states can result.

Next, parameters that dictate the value of n₀ that stabilizes the Fock state are described. The n-photon BIC condition, in the language of this theory, is Re Kₗ(ω_{n,n-1})=0. Suppose the zero of the loss function Kₗ(ω) occurs at some frequency ω₀ (the BIC frequency). Then, Kₗ around ω₀ may be expanded as Re Kₗ(ω)≈c₂(ω−ω₀)². thus

$${n}_{0} = \frac{{Δ}_{0}}{2 β} + 1$$

where Δ₀=ω₀−ω_{α} is the detuning of the linear resonance from the BIC frequency. This simple equation shows that the order of the Fock state can be controlled by simply tuning the resonator frequency (see FIG. 1F), and that there are discrete detunings that lead to Fock states. This equation also reveals that larger single-photon nonlinearities and smaller detunings lead to smaller photon numbers, while smaller single-photon nonlinearities (characteristic of “bulk material” nonlinearities) lead in principle to Fock states at larger photon numbers. The larger Fock states are more fragile, but even so, intense and extremely squeezed light can be realized; beyond what is typically achievable in resonators through normal nonlinear loss and thus this regime is still very interesting.

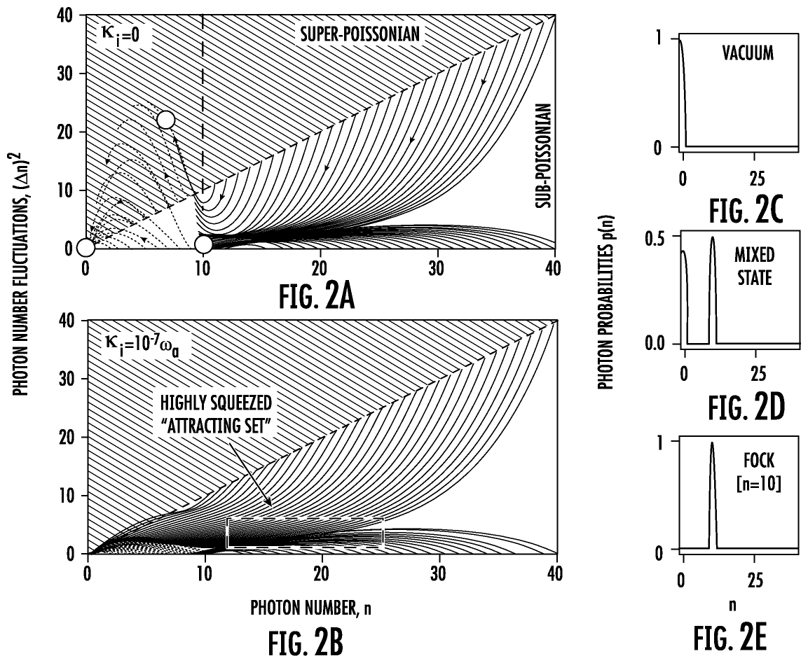

The dynamics of various quantum states undergoing the nonlinear radiation loss of FIG. 1D are illustrated in FIG. 2A, in a “phase space representation” where the phase space variables are mean and variance. Each line indicates a trajectory of some initial state. This shows the dynamics of a set of initially “Poissonian” states with shot noise photon number fluctuations, as well as initial Fock states. Consider the dynamics of the Poissonian states with mean greater than n₀=10. As shown in FIG. 2E, for a true BIC, the trajectories move towards a Fock state of order 10. As shown in FIG. 2C, states with mean sufficiently below n₀=10 decay to vacuum, as expected. Intriguingly, initial states that have significant probability to be both at n<10 and n≥10 lead to a mixed state with some probability of being in vacuum and some probability of being a Fock state, as shown in FIG. 2D. It is worth pausing to emphasize the striking-ness of this effect. In all known photonic systems, in the absence of a driving field, the only stable state is the vacuum state with zero photons. All finite photon-number states dissipate. In the systems examined here, all but two states dissipate: the zero photon state, and the no-photon Fock state. This type of bistability differs from conventional bistability in Kerr systems in that with no driving amplitude, there is only a single stable state (vacuum). Further, in conventional systems, Fock states are not steady states. FIG. 2B is similar to FIG. 2A, but in this scenario, the internal loss (κi) is equal to 10⁻⁷ ωa. This scenario cannot achieve Fock states but flow towards heavily number-squeezed (sub-Poissonian) states with far less noise (variance) than their mean.

The example in FIG. 3A is meant to show how to generate close approximations of Fock states with large photon numbers. Such platforms should be realized using sizeable single-photon nonlinear strengths β. The system of FIG. 3A is formed by coupling excitons to a resonator which is then coupled to a waveguide. In this embodiment, a photonic crystal slab 34 may be utilized. Holes 33 are disposed in the slab 34, as described above. Excitons are supported by the quantum well 30. The hollow portion, which is devoid of holes 33, represents the waveguide 31. The reflector 32 is disposed on the end of the waveguide 31. This reflector 32 may be constructed using any of the techniques described above. Thus, this configuration is similar to that shown in FIG. 1A. The coupling between exciton and resonator leads to exciton-polaritons. From experiments, these exciton-polaritons are known to:
(a) reach strong coupling, with measured Rabi splittings exceeding the decay rate by 1-2 orders-of-magnitude;
(b) be well-described by a driven single-mode Kerr Hamiltonian (with damping), as in Eq. (2), with the lower polariton serving an “effective photon” (or photonic quasiparticle); and
(c) present the strong nonlinearities that are needed.

The nonlinearities already present (β˜10⁻⁵ω_{α}) are already much larger than what: is available in diffraction-limited microcavities of bulk nonlinear optical materials such as GaAs and GaP. In recent experiments, exciton-polaritons in microcavities have also been shown to present the characteristic optical bistability of Kerr systems, with concomitant squeezing. Even more recently, it has been shown that polariton-polariton interactions are now strong enough to lead to antibunching of light, with promising prospects for photon blockade (or more appropriately, polariton blockade) upon improvement of the exciton lifetime (which in those experiments, was on the order of 10 ps). The most recent experiments have even managed to couple exciton polaritons in GaAs to optical bound states in the continuum in one-dimensionally periodic gratings, forming polariton BICs with measured lifetimes approaching 1 ns (similar to a lower-bound associated with exciton dispersion, discussed for a different material platform). All in all, this suggests the use of such exciton-polaritons as a promising platform to realize the physics described here, motivating its choice as the main example.

A protocol for “loading” Fock and highly squeezed states is described. It is illustrated in FIG. 3B and starts by injecting a short pulse through the resonator. The field amplitude has a real component and an imaginary component. In FIG. 3B, the horizontal axis is proportional to the real component, while the vertical axis represents the imaginary component. This pulse is short compared to the timescale of the nonlinearity and the dissipation. In some embodiments, the pulse may be between 1 femtosecond and 1 picosecond in duration. More generally, the pulse duration is much shorter than the inverse full wave half maximum (FWHM) of the frequency dependence of the resonator lifetime. Its purpose is to load an initial state with mean number of photons greater than n₀. In another embodiment, a continuous wave source may be used to inject light instead, leading to a sub-Poissonian or Fock steady state. The state can be somewhat arbitrary. Then, after the pulse passes, the dynamics are governed by the nonlinear dissipation of Eqs. (1-3). The simulated dynamics of the overall quantum state of the cavity, are visualized in FIG. 3B through the Husimi Q functions. Initially, the state is vacuum. After the pump pulse, it is in a coherent state. The subsequent decay leads to a stretching of the Q function in phase (angular direction), while the overall photon number decreases (this meniscus shape is well-documented in early works on Kerr squeezing). Then, after long times, the system approaches a Fock state.

FIG. 3C shows the simulated photon probabilities. In each of these graphs, the resonator is tuned to a different frequency. In the leftmost graph, the resonator is tuned such that a Fock state is created with a photon number of 30. In the third and fourth graphs, the resonator is tuned such that a Fock state is created with a photon number of 20 and 10, respectively. The various lines within each graph show the progression of the photon number over time. The main observation is that as a function of time, the photon noise of the coherent state condenses: in other words, the nonlinear loss leads to photon number squeezing, until eventually, for longer times, the distribution converges to a Fock state (here, at times on the order of several hundred ns). But already, for shorter times (e.g., 700 ps or 7 ns), there is significant photon number squeezing (roughly 10 dB) and strong fidelity enhancement for Fock state generation. The limiting Fock state order depends on the detuning. For detunings which cause the nonlinear loss to vanish at an integer photon number, the Fock state is produced with fidelity 1. Meanwhile, for detunings for which the loss zero is non-integral, the resonator does not reach a Fock state, as there is no integer photon number for the distribution to get stuck at, leading to a “failed” Fock state. This is shown in the second graph in FIG. 3C.

FIG. 3D shows the time-dependent photon-number squeezing for different levels of external linear loss. Importantly, even for realistic linear losses, it is possible to achieve substantial number squeezing, such as beyond the 3 dB limit in resonators. Parameters are the same as in FIG. 1F. This figure further assumes an exciton-photon Rabi frequency of 1.8 meV, a nonlinear exciton-exciton energy of 20 μeV·μm², and an exciton-photon hybridization coefficient of 0.5. The input pulse preparing the coherent state is assumed to be 10 fs in duration and contain about 1000 photons (as from an attenuated pulsed laser). Note also that the light can be readily outcoupled to the far-field by means of a secondary waveguide above the quantum well.

In optics, the realization of the nonlinear loss of FIG. 1E and the n-photon BIC effect predicted in FIG. 2A is within reach. FIG. 3A indicates possibilities for combining strong exciton-polariton nonlinearities with photonic bound states in the continuum to realize mesoscopic light states with Δn˜1, while the mean is much larger than one. As discussed above, the nonlinearities are already strong enough, and low external losses have also very recently been achieved.

Minimally, all that is required is a BIC (or a good approximation of a BIC) which appears for a certain index of refraction, Kerr and nonlinearity (third-order optical nonlinearity). The types of architectures to realize the former (illustrated in FIGS. 1A-1C) have already been realized (without Kerr nonlinearity). Fock states with extremely high fidelities require sizable nonlinearities, but sufficiently interesting intensity squeezing may already be achievable in the macroscopic domain for bulk-type nonlinearities (e.g., in silicon or InGaAs). Nanophotonic systems more broadly, exploiting coupled cavities based on high-Q ring resonators and microspheres, or photonic crystal cavities may enable the construction of almost arbitrary nonlinear losses, and even with very little background loss (though with weaker nonlinearities, leading to high squeezing rather than Fock state generation). Moreover, such systems have the advantage of being implementable even at room temperature, due to the optical photon frequency being large compared to thermal energies, and the material losses being low even at room temperature.

While FIGS. 1A-1C show three different configurations that may be used to create these Fock states or intensity squeezed states, there are other configurations as well.

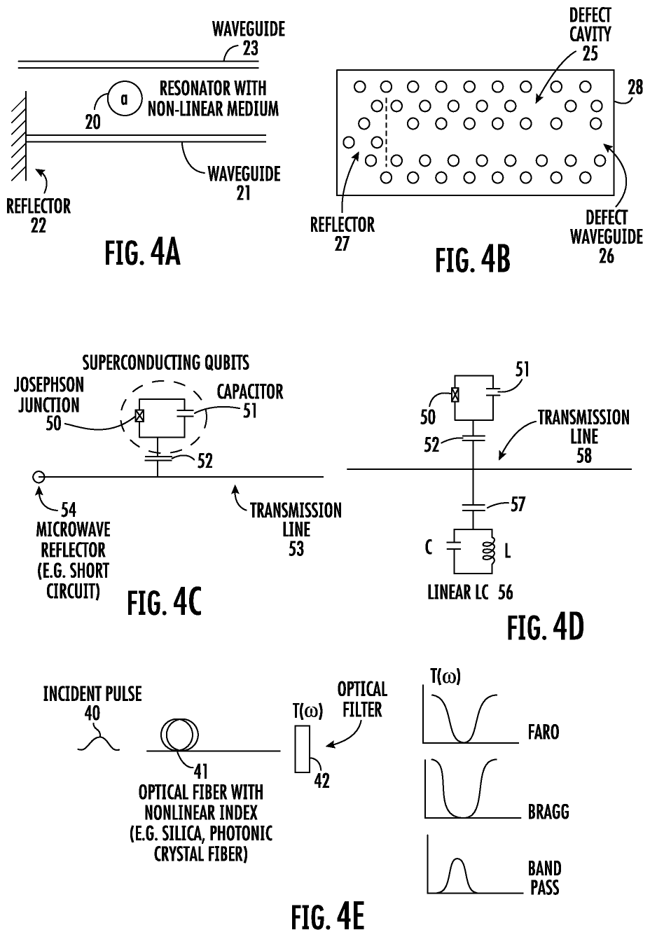

FIG. 4A shows a variation of the embodiment shown in FIG. 1A. In this embodiment, a resonator 20 with a nonlinear medium is evanescently coupled to a cavity 21, which may be a waveguide. As described above, this resonator 20 may be a ring resonator or a defect resonator. One end of the cavity 21 is terminated by a reflector 22, which may be a mirror. In the case of a defect resonator, the reflector 22 may be realized through a photonic bandgap, similar to the case of FIG. 3A. Namely, the row of filled holes in the crystal slab forms a defect waveguide, as the waveguide supports states which are in the bandgap of the photonic crystal defined by the periodic array of holes (see holes 33 in FIG. 3A). Additionally, a second waveguide 23 is also disposed near the resonator 20, such that the resonator 20 is also coupled to the second waveguide 23.

Although not shown, the embodiment of FIG. 1B may also be modified to include a second waveguide, which is coupled to one or both of the resonators.

FIG. 4B shows an embodiment that utilizes a photonic crystal slab 28 having a plurality of defect cavities 25. These defect cavities 25 are coupled to a defect waveguide 26, which is terminated on one end with a reflector 27. Note that this configuration is similar to that shown in FIG. 3A, however, the nonlinearity is achieved using a mechanism other than a quantum well. For example, as described above, the nonlinearity may be within the photonic crystal slab 28 itself, or may be a nonlinear medium that is disposed close to the defect cavity 25.

As noted above, in some embodiments, the nonlinear medium may display Kerr nonlinearity (third order nonlinearity). This may be accomplished through the use of GaAs, Ge, ZnTe (and general semiconductors), Si, Si₃N₄, GaP, silica, chalcogenide glasses such as As₂S₃ or As₂Se₃, or nonlinear gases such as CS. In yet other embodiments, the nonlinear medium may be realized by a semiconductor quantum well (sustaining excitons) in close proximity to the optical resonator. The semiconductor well may be made from GaAs, or transition metal dichalcogenides, such as WS₂, WSe₂, MoS₂, or MoSe₂.

More extreme nonlinear dissipation, enabling one- and few-photon Fock states, may be achieved by combining these resonators with matter systems supporting single-photon-scale nonlinearities (e.g., cavity QED systems with photon blockade or Rydberg atoms with BICs).

Another worthwhile platform for implementing the physics described here is in superconducting circuits. Although several techniques already exist for creating Fock states in superconducting qubits, the current approach, which makes use only of Kerr nonlinearity and linear loss engineering, is quite flexible, and may be beneficial even when implemented in superconducting qubit systems. For example, it would enable the direct conversion of a microwave probe into a Fock state of a Kerr nonlinear microwave resonator, which may be formed by coupling a Josephson junction with modest anharmonicity to a linear microwave resonator. From a nonlinearity and external loss perspective, the capabilities are present to demonstrate Fock-state and extreme squeezing with n-photon BICs. Beyond providing a useful proving ground for the concepts developed here, this technique provides a path to easily tune the Fock state order (just by changing the detuning), and achieve fairly high Fock-state numbers with high fidelity.

To summarize, a fundamentally new form of nonlinear dissipative interaction for photons is disclosed. At the most basic level, the nonlinear arises dissipation from combining nonlinearity and leaky modes with frequency-dependent radiation loss. When the nonlinearity is Kerr, this combination induces a decay rate for photons with an intensity-dependence qualitatively beyond what is offered by commonly employed multiphoton and saturable absorbers. When the leaky-mode is an approximate BIC, the nonlinear dissipation creates a “potential” in photon number which facilitates the generation of Fock states and highly intensity-squeezed states.

As discussed earlier, the theory developed to describe such effects is quite general, as it is applicable to any Kerr nonlinear oscillator coupled to one or more continuua with frequency-dependent couplings. The consideration of Kerr nonlinearity is not so restrictive: many systems in nature with self-interactions are described by a Kerr Hamiltonian, with some value of the β parameter which can be predicted from first-principles, or measured. Such systems include: bulk optical materials (where Kerr comes from χ⁽³⁾) exciton-polaritons (where Kerr comes from Coulomb interactions), superconducting circuits (where Kerr comes from nonlinear inductance), magnons (where Kerr comes from magnon-magnon interaction), Rydberg atoms (where single-photon nonlinearities arise from Rydberg blockade), and cavity-QED systems (where single-photon nonlinearities arise from photon blockade).

This disclosure establishes a new connection between two highly active fields: (1) radiation loss engineering, which has primarily been explored in classical optics in the context of BICs, exceptional points, and non-Hermitian photonics and (2) quantum-state engineering, where the use of nonlinear dissipation to engineer quantum states is well-appreciated. For example, beyond systems with BICs explored here, quantum nonlinear systems with exceptional points, which are known to be sensitive to small changes in the refractive index may be created. Moreover, the general platform introduced here (nonlinearity plus frequency-dependent radiation loss) suggests the possibility of using second-order nonlinearity instead of Kerr. In these embodiments, the non-linear medium may be a second order medium, such as potassium dihydrogen phosphate (KDP), potassium titanyl phosphate (KTP), beta barium borate (BBO), lithium niobate (LN) or periodically poled lithium niobate (PPLN). Since second-order nonlinearities enable phase-sensitive loss (and gain), it is clear that such systems enable qualitatively different opportunities. Such nonlinear losses, arising from second-and third-order nonlinearities may very well give paths towards stablizing other quantum optical states that are of interest to the community (Schrodinger cat states, GKP states, cluster states, and the like).

It is clear that the concept demonstrated here also can be applied in other systems realizing the same physics. For example:
Josephson junctions possess a nonlinear inductance, which, when combined with a capacitor, realize a nonlinear LC resonator with Kerr nonlinearity. The excitations of this LC resonator (transmon qubit) can be dissipated by coupling it capacitively to a transmission line, and frequency-dependent outcoupling can be realized. In one embodiment, shown in FIG. 4C, the Josephson junction 50 is combined with a capacitor 51 and coupled to a transmission line 53 through a coupling capacitor 52. The transmission line 53 is terminated on one end with a microwave reflector 54, which may be a short circuit. In another embodiment, shown in FIG. 4D, the nonlinear LC (comprising the Josephson junction 50 and the capacitor 51) and a linear LC circuit 56 are each capacitively coupled to a common transmission line 58 using capacitors 52 and 57, respectively. line The transmission 58 is unterminated.
The general principle here is the creation of a loss rate for photons which depends on intensity. As shown in FIG. 4E, this can also be realized in the following fashion: by inducing a spectral transformation on an incident light pulse 40. For example, the incident light pulse 40 may be passed through a nonlinear medium 41. This nonlinear medium may be an optical fiber with a nonlinear index, such as silica or photonic crystal fiber. Alternatively, this nonlinear medium may be a nonlinear cavity. The output is then passed through a spectral filter 42, wherein the filtered intensity depends on the input intensity (because the spectral transformation depends on input intensity). The spectral filter 42 may be a filter with a Fano lineshape, a Bragg filter, a Fabry-Perot filter, or a bandpass filter. Properties of these filters are shown on the right side of FIG. 4E. This realizes a nonlinear loss which can produce sub-Poissonian states and Fock states. Note that in some embodiments, a chain may be created wherein each element of the chain comprises a nonlinear medium 41 and a spectral filter 42. In this way, successive optimal filtering of the incident light may be performed.

The present disclosure differs significantly from the prior art. The new effect described herein (n-photon bound states in the continuum) is the only one that can potentially allow for deterministic creation of large multiphoton Fock states in optics.

The present disclosure is not to be limited in scope by the specific embodiments described herein. Indeed, other various embodiments of and modifications to the present disclosure, in addition to those described herein, will be apparent to those of ordinary skill in the art from the foregoing description and accompanying drawings. Thus, such other embodiments and modifications are intended to fall within the scope of the present Further, although the present disclosure has been disclosure. described herein in the context of a particular implementation in a particular environment for a particular purpose, those of ordinary skill in the art will recognize that its usefulness is not limited thereto and that the present disclosure may be beneficially implemented in any number of environments for any number of purposes. Accordingly, the claims set forth below should be construed in view of the full breadth and spirit of the present disclosure as described herein.

What is claimed is:

1. An apparatus for storing electromagnetic energy, comprising:
an electromagnetic resonator, and
a nonlinear medium;
wherein the electromagnetic resonator contains a resonance whose lifetime τ depends on resonance frequency (τ=τ(ω)) and/or wherein the electromagnetic resonator contains a resonance whose lifetime τ depends on a spatial distribution of its index of refraction, n(r), wherein r denotes a spatial position of constituent components of the electromagnetic resonator, such that τ=τ(n(r).

2. The apparatus of claim 1, wherein the dependence of the resonance lifetime on frequency has a maximum as a function of frequency and/or wherein the dependence of the resonance lifetime on index of refraction has a maximum as a function of the index of refraction distribution, or the index of refraction of any one constituent component of the electromagnetic resonator.

3. The apparatus of claim 1, wherein the nonlinear medium is a second-order nonlinear medium, and is one of KDP, KTP, BBO, LN, and PPLN.

4. The apparatus of claim 1, wherein the nonlinear medium is a third-order nonlinear medium (a Kerr nonlinear medium).

5. The apparatus of claim 4, wherein the nonlinear medium is GaAs, Ge, ZnTe (and general semiconductors), Si, Si₃N₄, GaP, silica, As₂S₃, As₂Se₃, other chalcogenide glasses, CS₂ or other nonlinear gases.

6. The apparatus of claim 1, wherein the nonlinear medium is realized by a semiconductor quantum well (sustaining excitons) in close proximity to the electromagnetic resonator.

7. The apparatus of claim 6, wherein the semiconductor quantum well is comprised of GaAs, WS₂, WSe₂, MoS₂, MoSe₂ or other transition metal dichalcogenides.

8. The apparatus of claim 1, wherein the electromagnetic resonator is built from two ring resonators coupled evanescently to a waveguide; wherein either one or both resonators contain the nonlinear medium.

9. The apparatus of claim 8, comprising at least one additional waveguide, wherein the at least one additional waveguide is coupled to either one or both resonators.

10. The apparatus of claim 1, wherein the electromagnetic resonator is built from two photonic crystal defect cavities, coupled to a single photonic crystal waveguide, and wherein either one or both resonators contain the nonlinear medium.

11. The apparatus of claim 10, comprising at least one additional waveguide, wherein the at least one additional waveguide is coupled to either one or both resonators.

12. The apparatus of claim 1, wherein the electromagnetic resonator is realized by a photonic crystal slab with a resonance at some wavevector, whose lifetime achieves a sharp maximum as a function of wavevector, or index of refraction.

13. The apparatus of claim 12, wherein the photonic crystal slab material is also a nonlinear medium, or wherein the photonic crystal slab is in proximity to a nonlinear medium.

14. The apparatus of claim 1, wherein the electromagnetic resonator is realized by a photonic crystal slab terminated laterally by a photonic crystal heterostructure.

15. The apparatus of claim 1, wherein the electromagnetic resonator is a single ring resonator, coupled to one or more optical waveguides; with one of the optical waveguides being terminated on one end by a broadband reflector.

16. The apparatus of claim 1, wherein the electromagnetic resonator is a photonic crystal defect cavity, coupled to one or more photonic crystal defect waveguides, with one of the photonic crystal waveguides being terminated by a backreflector, which is realized through a photonic bandgap.

17. The apparatus of claim 1, wherein the electromagnetic resonator and nonlinearity are realized by coupling one weakly anharmonic Josephson junction, realizing Kerr nonlinearity, and a LC resonator, to a common transmission line.

18. The apparatus of claim 1, wherein the electromagnetic resonator and nonlinearity are realized by coupling one weakly anharmonic Josephson junction, realizing Kerr nonlinearity, to a transmission line which is terminated on one end by a microwave reflector.

19. An apparatus for storing electromagnetic energy at any frequency, comprising:
a cavity containing:
an electromagnetic resonator, and
a nonlinear medium;
wherein the electromagnetic resonator contains a resonance whose lifetime τ depends on a number of photons in the cavity, or equivalently, an intensity in the cavity.

20. An apparatus for preparing quantum mechanical states of radiation, including sub-Poissonian states and Fock states, in a single resonant optical cavity, comprising:
the apparatus of claim 1; and
a pulsed laser, to inject initial photons into the resonant optical cavity.

21. The apparatus of claim 20, wherein the pulsed laser is between 1 fs and 1 ps in duration.

22. An apparatus for preparing quantum mechanical states of radiation, including sub-Poissonian states and Fock states in a single resonant optical cavity, comprising:
the apparatus of claim 1; and
a continuous wave laser, to pump photons into the resonant optical cavity.

23. An apparatus for preparing quantum mechanical states of radiation, including sub-Poissonian states and Fock states, which is freely propagated in free space, comprising:
a nonlinear system which imparts a transformation to an optical spectrum of an incident light pulse; and
a spectral filter to induce nonlinear loss for light emitted from the nonlinear system.

24. The apparatus of claim 23, wherein the nonlinear system is an optical fiber with dispersion and the spectral filter is a Bragg filter, a filter with a Fano lineshape, or a Fabry-Perot filter.

25. The apparatus of claim 24, wherein the apparatus comprises a chain having a plurality of elements, wherein each element of the chain comprises the optical fiber and the spectral filter, to realize successive optimal filtering of the incident light.
